(19) United States
(12) Patent Application Publication
(10) Pub. No.: US 2016/0170115 A1
(43) Pub. Date: Jun. 16, 2016

(54) WIRE GRID POLARIZER AND METHOD OF MANUFACTURING THE SAME

(71) Applicant: Samsung Display Co. Ltd., Yongin-City (KR)

(72) Inventors: Tae Woo KIM, Seoul (KR); Min Hyuck KANG, Seoul (KR); Eun Ae KWAK, Gunpo-si (KR); Moon Gyu LEE, Suwon-si (KR); Hyeong Gyu JANG, Asan-si (KR)

(21) Appl. No.: 14/681,952

(22) Filed: Apr. 8, 2015

(30) Foreign Application Priority Data
Dec. 10, 2014 (KR) 10-2014-0177433

(51) Int. Cl. G02B 5/30; H01J 37/32

(52) U.S. Cl. CPC G02B 5/3058; H01J 37/32009

(57) ABSTRACT

A method of manufacturing a wire grid polarizer is provided. The method includes: forming an electrical conductive layer on a substrate; forming a guide pattern layer on the electrical conductive layer, wherein the guide pattern layer includes two or more linear structures separated from one another; forming a fluorocarbon surface modification layer on each of the linear structures using a fluorine-based gas plasma treatment; and forming a neutral layer on the electrical conductive layer, wherein the neutral layer has a nonselective affinity with repeating units of a block copolymer.

This application claims priority from Korean Patent Application No. 10-2014-0177433 filed Dec. 10, 2014 in the Korean Intellectual Property Office, the disclosure of which is incorporated herein by reference in its entirety.

### BACKGROUND

1. Technical Field

The present disclosure generally relates to a wire grid polarizer and a method of manufacturing the same.

2. Description of the Related Art

A wire grid may include an array of parallel conductive wires for polarizing light so as to produce an electromagnetic wave of a specific polarization. For example, a wire grid structure having a smaller period than a wavelength of unpolarized incident light can reflect light along a polarization axis in the direction of wires and transmit light along a polarization axis perpendicular to the direction of the wires. Unlike an absorptive polarizer which absorbs reflected polarized light, a wire grid polarizer can transmit reflected polarized light.

### SUMMARY

Embodiments of the inventive concept provide a wire grid polarizer having a high aperture ratio and a method of manufacturing the same.

According to an embodiment of the inventive concept, a method of manufacturing a wire grid polarizer is provided. The method includes: forming an electrical conductive layer on a substrate; forming a guide pattern layer on the electrical conductive layer, wherein the guide pattern layer includes two or more linear structures separated from one another; forming a fluorocarbon surface modification layer on each of the linear structures using a fluorine-based gas plasma treatment; and forming a neutral layer on the electrical conductive layer, wherein the neutral layer has a nonselective affinity with repeating units of a block copolymer.

In some embodiments, the fluorine-based gas may include at least one of sulfur hexafluoride (SF₆) and nitrogen hexafluoride (NF₆), or a carbon fluoride-based gas.

In some embodiments, the fluorine-based gas may be a gas mixture comprising a carbon fluoride-based gas and at least one of sulfur hexafluoride (SF₆) and nitrogen hexafluoride (NF₆). A content of the carbon fluoride-based gas may be equal to or less than 30% of a total content of the fluorine-based gas.

In some embodiments, the neutral layer may be made of a random copolymer comprising a first repeating unit and a second repeating unit. The random copolymer may include at least one of polystyrene-r-polybutadiene (PS-r-PB), polystyrene-r-polyisoprene (PS-r-PI), polystyrene-r-poly(methyl-methacrylate) (PS-r-PMMA), polystyrene-r-poly(2-vinylpyridine) (PS-r-P2VP), polystyrene-r-poly(ferrocenyl-dimethylsilane) (PS-r-PFDMS), polystyrene-r-poly(tert-butylacrylate) (PS-r-PtBA), polystyrene-r-poly(ferrocenylethylmethylsilane) (PS-r-PFEMS), polyisoprene-r-poly(ethyleneoxide) (PI-r-PEO), polybutadiene-r-poly(butadiene-r-vinylpyridinium) (PB-r-PVP), poly(tert-butylacrylate)-r-poly(cinnamoyl-ethylmethacrylate) (PtBA-r-PCEMA), polystyrene-r-polylactide (PS-r-PLA), poly(α-methylstyrene)-r-poly(4-hydroxystyrene) (PαMS-r-PHS), pentadecyl phenol modified polystyrene-r-poly(4-vinylpyridine) (PPDPS-r-P4VP), poly(styrene-r-ethyleneoxide) (PS-r-PEO), polystyrene-r-poly(dimethyl siloxane) (PS-r-PDMS), polystyrene-r-polyethylene (PS-r-PE), polystyrene-r-poly(ferrocenyl dimethyl silane) (PS-r-PFS), polystyrene-r-poly(paraphenylene) (PS-r-PPP), PS-r-PB-r-PS, PS-r-PI-r-PS, poly(propyleneoxide))-r-PEO (PPO-r-PEO), and poly(4-vinyl-phenyldimethyl-2-propoxysilane) (PVPDMPS)-r-PI-r-PVPDMPS, PS-r-P2VP-r-PtBMA), or a copolymer thereof.

In some embodiments, forming the guide pattern layer may include: forming an organic matter layer on the electrical conductive layer; forming the two or more linear structures by etching the organic matter layer; and reducing a width of each of the linear structures.

In some embodiments, the width of each of the linear structures may be reduced using a plasma etching process.

In some embodiments, the plasma etching process may be an oxygen plasma etching process.

In some embodiments, the method may further include: forming a self-assembled block copolymer layer in a trench between surface-reformed linear structures, wherein the self-assembled block copolymer layer may include a first domain formed by self-assembly of the first repeating unit and a second domain formed by self-assembly of the second repeating unit; and removing one of the first domain and the second domain.

In some embodiments, forming the self-assembled block copolymer layer may include: forming a block copolymer layer in a trench between the linear structures, wherein the block copolymer layer may include the first repeating unit and the second repeating unit; and annealing the block copolymer layer.

In some embodiments, the block copolymer layer may include at least one of polystyrene-b-polybutadiene (PS-b-PB), polystyrene-b-polyisoprene (PS-b-PI), polystyrene-b-poly(methyl methacrylate) (PS-b-PMMA), polystyrene-b-poly(2-vinylpyridine) (PS-b-P2VP), polystyrene-b-poly(ferrocenyl-dimethylsilane) (PS-b-PFDMS), polystyrene-b-poly(tert-butylacrylate) (PS-b-PtBA), polystyrene-b-poly(ferrocenylethylmethylsilane) (PS-b-PFEMS), polyisoprene-b-poly(ethyleneoxide) (PI-b-PEO), polybutadiene-b-poly(butadiene-b-vinylpyridinium) (PB-b-PVP), poly(tert-butylacrylate)-b-poly(cinnamoyl-ethylmethacrylate) (PtBA-b-PCEMA), polystyrene-b-polyactide (PS-b-PLA), poly(α-methylstyrene)-b-poly(4-hydroxystyrene) (PαMS-b-PHS), pentadecyl phenol modified polystyrene-b-poly(4-vinylpyridine) (PPDPS-b-P4VP), poly(styrene-b-ethyleneoxide) (PS-b-PEO), polystyrene-b-poly(dimethyl siloxane) (PS-b-PDMS), polystyrene-b-polyethylene) (PS-b-PE), polystyrene-b-poly(ferrocenyl dimethyl silane) (PS-b-PFS), polystyrene-b-poly(paraphenylene) (PS-b-PPP), PS-b-PB-b-PS, PS-b-PI-b-PS, poly(propyleneoxide)-b-PEO PPO-b-PEO, and poly(4-vinyl-phenyldimethyl-2-propoxysilane) (PVPDMPS)-b-PI-b-PVPDMPS, PS-b-P2VP-b-PtBMA), or a block copolymer thereof.

In some embodiments, the annealing of the block copolymer layer may include thermal annealing or solvent annealing.

In some embodiments, the method may further include patterning the electrical conductive layer using a remaining domain and the surface-modified linear structures.

In some embodiments, the substrate may include at least one of glass, quartz, and a polymer compound.

In some embodiments, the electrical conductive layer may be a metal layer.

In some embodiments, the metal layer may include at least one of aluminum (Al), chrome (Cr), silver (Ag), copper (Cu), nickel (Ni) titanium (Ti), cobalt (Co), and molybdenum (Mo), or any alloy thereof.

According to another embodiment of the inventive concept, a wire grid polarizer is provided. The wire grid polarizer includes: a substrate, a plurality of conductive wire patterns disposed on the substrate; an organic matter layer disposed on the conductive wire patterns; and a fluorocarbon surface modification layer disposed on the organic matter layer.

In some embodiments, the plurality of conductive wire patterns may include a first conductive wire pattern having a first width and a second conductive wire pattern having a second width. The second width may be greater than the first width.

In some embodiments, the organic matter layer and the fluorocarbon surface modification layer may be disposed on the second conductive wire pattern.

In some embodiments, the wire grid polarizer may further include a remaining domain layer disposed on the first conductive wire pattern.

In some embodiments, the wire grid polarizer may further include a reflective layer. The organic matter layer and the fluorocarbon surface modification layer may be disposed on the reflective layer.

### BRIEF DESCRIPTION OF THE DRAWINGS

FIGS. 1, 2, 3, 4, 5, 6, 7, 8, 9, and 10 illustrate cross-sectional views of an exemplary wire grid polarizer at different stages of fabrication according to a method of manufacturing the wire grid polarizer.

FIG. 11 illustrates a cross-sectional view of a wire grid polarizer according to an embodiment.

FIG. 12 illustrates a cross-sectional view of a wire grid polarizer according to another embodiment.

FIG. 13 illustrates a cross-sectional view of a wire grid polarizer according to a further embodiment.

FIG. 14 illustrates a schematic cross-sectional view of a lower substrate of a display device according to an embodiment.

FIGS. 15 and 16 illustrate cross-sectional views of another exemplary wire grid polarizer at different stages of fabrication according to a method of manufacturing the wire grid polarizer.

FIG. 17 illustrates a schematic cross-sectional view of a lower substrate of a display device according to another embodiment.

### DETAILED DESCRIPTION

Features of the inventive concept and methods of accomplishing the same may be understood more readily with reference to the following detailed description of exemplary embodiments and the accompanying drawings. The inventive concept may be embodied in many different forms and should not be construed as being limited to the embodiments set forth herein. Rather, these embodiments are provided so that this disclosure sufficiently conveys the inventive concept to one of ordinary skill in the relevant art.

In the drawings, the thicknesses of layers and regions may be exaggerated for clarity. It will be understood that when an element or layer is referred to as being “on,” “connected to” or “coupled to” another element or layer, the element or layer can be directly on, connected or coupled to another element or layer, or with one or more intervening elements or layers being present. In contrast, when an element is referred to as being “directly on,” “directly connected to” or “directly coupled to” another element or layer, there are no intervening elements or layers present. As used herein, connected may refer to elements being physically, electrically, operably, and/or fluidly connected to each other.

Like numbers refer to like elements throughout. As used herein, the term “and/or” includes any and all combinations of one or more of the associated listed items.

It will be understood that, although the terms “first,” “second,” “third,” etc. may be used herein to describe various elements, components, regions, layers and/or sections, the elements, components, regions, layers and/or sections should not be limited by those terms. Instead, those terms are merely used to distinguish one element, component, region, layer or section from another element, component, region, layer or section. Thus, a first element, component, region, layer or section described below could be easily termed a second element, component, region, layer or section without departing from the teachings of the present disclosure.

Spatially relative terms such as “below,” “lower,” “under,” “above,” “upper” and the like, may be used herein to describe the spatial relationship of one element or feature to another element(s) or feature(s) as illustrated in the figures. It will be understood that the spatially relative terms are intended to encompass different orientations of the device during use or operation, in addition to the orientation depicted in the figures. For example, if the device in the figures is turned over, elements described as “below” or “beneath” relative to other elements or features would then be oriented “above” relative to the other elements or features. Thus, the example term “below” can encompass both an orientation of above and below, depending on the orientation of the elements. The device may be otherwise oriented (rotated 90 degrees or at other orientations) and the spatially relative descriptors used herein interpreted accordingly.

The terminology used herein is for the purpose of describing certain embodiments and is not intended to limit the inventive concept. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof. Expressions such as “at least one of,” when preceding a list of elements, modify the entire list of elements and do not modify the individual elements of the list. Further, the use of “may” when describing embodiments refers to “one or more embodiments.” Also, the term “example” is intended to refer to an example or illustration. As used herein, the terms “use,” “using,” and “used” may be considered synonymous with the terms “utilize,” “utilizing,” and “utilized,” respectively.

Embodiments of the inventive concept will be herein described with reference to the attached drawings.

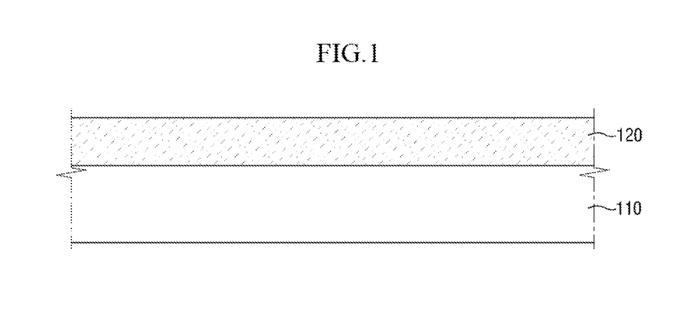

FIGS. 1, 2, 3, 4, 5, 6, 7, 8, 9, and 10 illustrate cross-sectional views of an exemplary wire grid polarizer at different stages of fabrication according to a method of manufacturing the wire grid polarizer.

Referring to FIG. 1, an electrical conductive layer 120 may be formed on a substrate 110. The electrical conductive layer 120 may be formed covering the entire surface of the substrate 110.

The substrate 110 may be made of any material capable of transmitting visible light. The material for the substrate 110 may be selected according to the purpose for which a product is used or in some instances, selected based on process considerations. Examples of the material may include glass, quartz, and various polymer compounds such as acrylic, triacetylcellulose (TAC), cyclic olefin copolymer (COC), cyclic olefin polymer (COP), polycarbonate (PC), polyethylene naphthalate (PET), polyimide (PI), polyethylene naphthalate (PEN), polyether sulfone (PES), or polyarylate (PAR). In some embodiments, the substrate 110 may be made of a flexible optical film.

The electrical conductive layer 120 may be made of any conductive material. For example, the electrical conductive layer 120 may be made of but not limited to, a metal material, more specifically, at least any one of aluminum (Al), chrome (Cr), silver (Ag), copper (Cu), nickel (Ni), titanium (Ti), cobalt (Co), and molybdenum (Mo), or an alloy of any of the above metals. The electrical conductive layer 120 can be formed using, for example, a sputtering method, a chemical vapor deposition (CVD) method, or an evaporation method.

In some embodiments, the electrical conductive layer 120 may include two or more layers. For example, a first electrical conductive layer (not illustrated) may be made of aluminum, and a second electrical conductive layer (not illustrated) may be made of titanium or molybdenum. If the first electrical conductive layer is made of aluminum, hillocks may be formed on the first electrical conductive layer depending on the process temperature in a subsequent process. Accordingly an upper surface of the first electrical conductive layer may be uneven, thereby degrading the optical characteristics of a product incorporating the first electrical conductive layer. To mitigate the above problem, the second electrical conductive layer made of titanium or molybdenum may be formed on the first electrical conductive layer. In particular, the second electrical conductive layer can provide a planar surface and cover hillocks that are formed on the first electrical conductive layer.

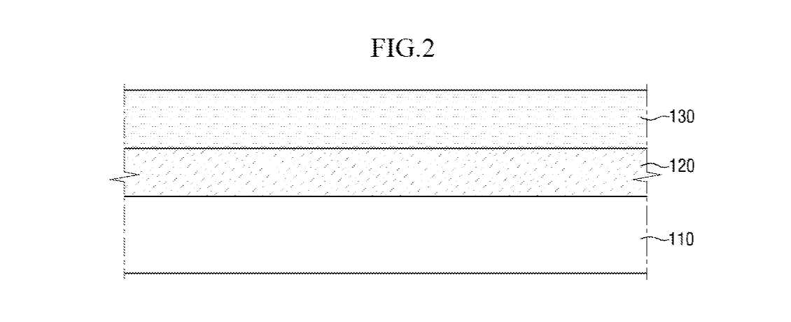

Referring to FIG. 2, an organic matter layer 130 may be formed on the electrical conductive layer 120. In one embodiment, the organic matter layer 130 may include a photoresist. The organic matter layer 130 may be formed covering the entire surface of the electrical conductive layer 120. The organic matter layer 130 may be patterned into linear structures to form a guide pattern layer.

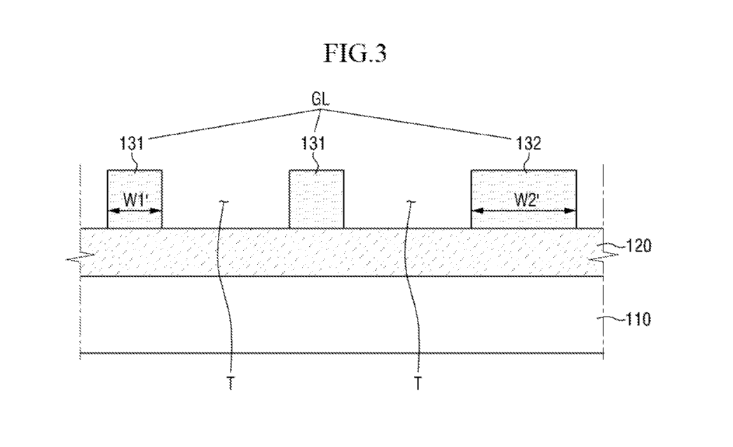

Referring to FIG. 3, a guide pattern layer GL including first linear structures 131 and a second linear structure 132 may be formed by etching or patterning the organic matter layer 130. The first linear structures 131 are separated from each other, and a trench T is formed between the first linear structures 131. The second linear structure 132 is separated from an adjacent first linear structure 131, and another trench T is formed between the adjacent first linear structure 131 and the second linear structure 132. The first linear structures 131 may be arranged parallel to each other to form a stripe pattern. The second linear structure 132 may be disposed parallel to the first linear structures 131.

Each of the first linear structures 131 has a first width W1′, and the second linear structure 132 has a second width W2′. The second width W2′ is greater than the first width W1′. In other words, each of the first linear structures 131 is narrower than the second linear structure 132.

In one embodiment, the organic matter layer 130 is made of a photoresist, and the first linear structures 131 and the second linear structure 132 may be formed by exposing and developing the organic matter layer 130 using a mask pattern. However, the inventive concept is not limited thereto. It is noted that various patterning techniques can be used to form the first linear structures 131 and the second linear structure 132.

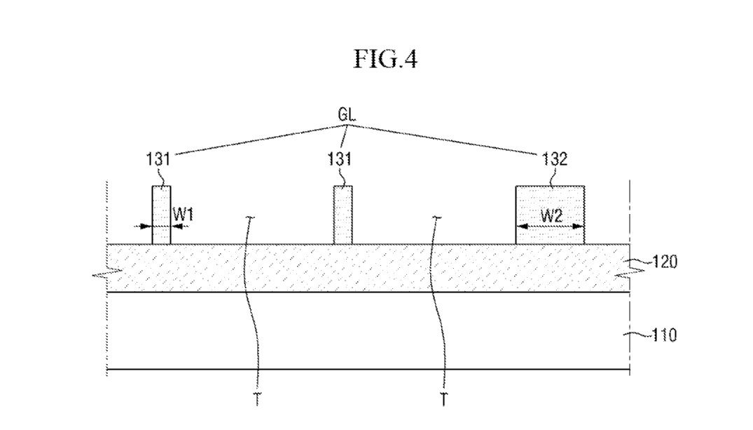

Referring to FIG. 4, a trimming process may be performed to reduce the widths W1′ and W2′ of the respective linear structures 131 and 132. As a result of the trimming process, each of the first linear structures 131 has a third width W1, and the second linear structure 132 has a fourth width W2. The third width W1 is smaller than the first width W1′, and the fourth width W2 is smaller than the second width W2′. As a result of the trimming process, the trenches T are wider in the structure of FIG. 4 than in the structure of FIG. 3. The third width W1 is smaller than the fourth width W2. As the first linear structures 131 and the second linear structure 132 become narrower, an aperture ratio of a wire grid polarizer may increase. Specifically, as the first linear structures 131 and the second linear structure 132 become narrower, the number of domains to be formed in the trenches T between the linear structures 131 and 132 may increase, thereby increasing the aperture ratio of the wire grid polarizer.

In one embodiment, the trimming process may be performed using a plasma etching process. Here any type of appropriate plasma can be used as long as it can reduce the widths of the first linear structures 131 and the second linear structure 132. In one embodiment, the trimming process may use a plasma that introduces a hydrophilic group to the surface of the electrical conductive layer 120. For example, oxygen (O₂) plasma that introduces a hydroxyl group (—OH) may be used.

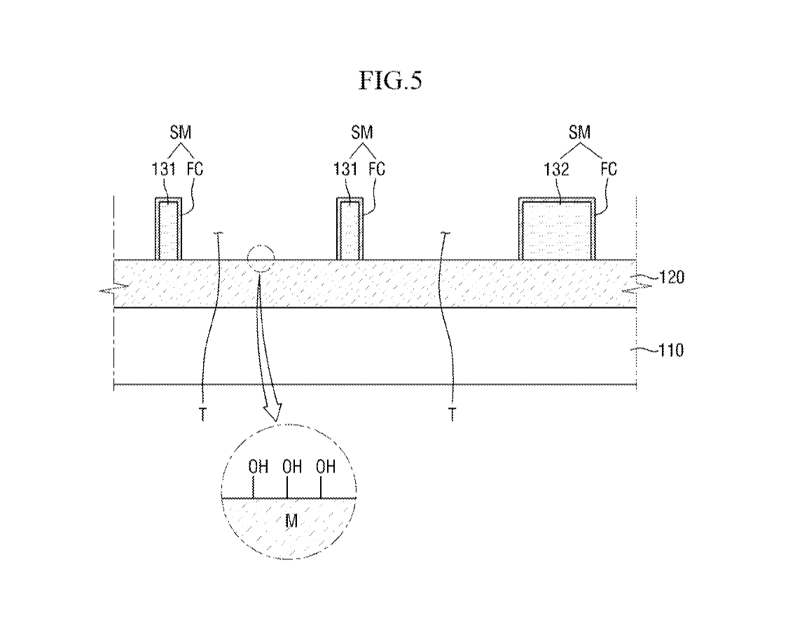

Referring to FIG. 5, a fluorocarbon surface modification layer FC may be formed on each of the first and second linear structures 131 and 132.

The first and second linear structures 131 and 132 may be surface-reformed by fluorine-based gas plasma treatment.

After the oxygen plasma treatment, hydroxyl groups (—OH) may be introduced to the surfaces of the linear structures 131 and 132 and the surface of the electrical conductive layer 120. The fluorine-based gas plasma treatment then causes the hydroxyl groups on the surfaces of the linear structures 131 and 132 to be substituted by fluorocarbon. However, some hydroxyl groups (—OH) may still exist on the surface of the electrical conductive layer 120. Although linear structures SM surface-reformed with fluorocarbon are not chemically bonded to a random copolymer (as described later in the specification), the electrical conductive layer 120 may be chemically bonded to the random copolymer using the hydroxyl groups (—OH).

In one embodiment, the fluorine-based gas may be sulfur hexafluoride (SF₆), nitrogen hexafluoride (NF₆), a carbon fluoride-based gas, or a gas mixture of any of the above gases. For example, in one embodiment, the carbon fluoride-based gas may be C₄F₈, CHF₃, CH₂F₂, C₄F₈, CF₄, or C₂F₆.

In one embodiment, the gas mixture may include the carbon fluoride-based gas and at least one of sulfur hexafluoride (SF₆) and nitrogen hexafluoride (NF₆). The content of the carbon fluoride-based gas may be, for example, equal to or less than 30% of the total content of the gas mixture. It is noted that when the content of the carbon fluoride-based gas is equal to or less than 30% of the total content of the gas mixture, the fluorocarbon surface modification layer FC may be formed only on the surfaces of the first and second linear structures 131 and 132.

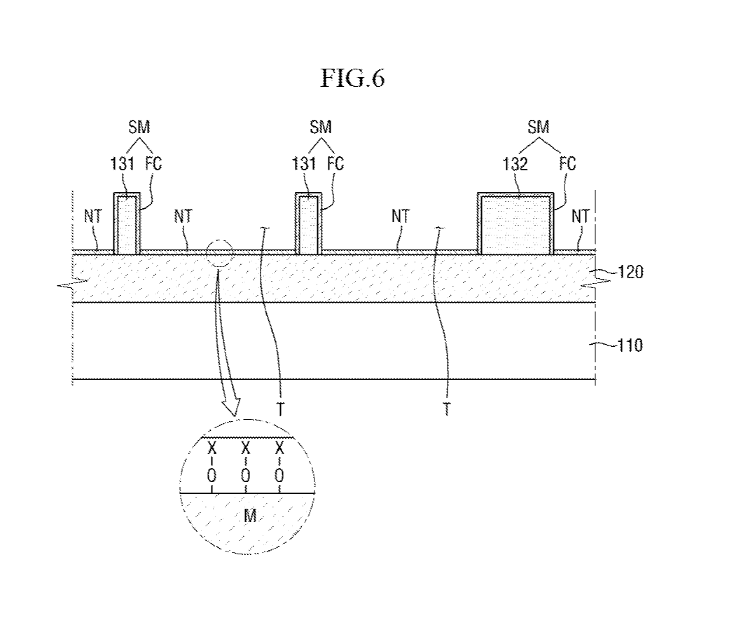

Referring to FIG. 6, a neutral layer NT may be formed in each of the trenches T between the surface-reformed linear structures SM. The neutral layer NT is formed in each of the trenches T between the surface-reformed linear structures SM after the oxygen plasma treatment. If the neutral layer NT is formed between the linear structures 131 and 132 before the oxygen plasma treatment, the neutral layer NT may be damaged by oxygen plasma and may not be able to play its role.

If any one of a first repeating unit and a second repeating unit of a block copolymer has a selective mutual attraction to or a selective chemical reaction with the electrical conductive layer 120, a microphase tends to be aligned horizontally to the substrate 110. The neutral layer NT may be made of a material having a nonselective or neutral mutual attraction or chemical reaction with the repeating units of the block copolymer. The neutral layer NT may be made of a material having a similar surface energy as the block copolymer. Since the neutral layer NT does not have selective affinity with the first repeating unit or the second repeating unit of the block copolymer, the neutral layer NT can therefore control the vertical alignment of the first repeating unit and the second repeating unit.

The neutral layer NT may be made of any material having a nonselective or neutral mutual attraction or chemical reaction with the repeating units of the block copolymer. In one embodiment, the neutral layer NT may be a random copolymer layer including a first repeating unit and a second repeating unit. The first repeating unit and the second repeating unit of a random copolymer may have the same or similar chemical properties as the first repeating unit and the second repeating unit of the block copolymer, as described later. For example, if the first repeating unit of the block copolymer is hydrophobic, the first repeating unit of the random copolymer may also be hydrophobic. If the second repeating unit of the block copolymer is hydrophilic, the second repeating unit of the random copolymer may also be hydrophilic.

Random copolymers (X) may be chemically bonded to the hydroxyl groups (—OH) introduced to the surface of the electrical conductive layer 120, thereby rendering the surface of the electrical conductive layer 120 neutral. For example, if the electrical conductive layer 120 is made of a metal (M), the random copolymers (X) may be chemically bonded to the metal (M) by oxygen (—O—) of the hydroxyl groups (—OH) introduced to the surface of the metal (M).

In one embodiment, a random copolymer (X) may be polystyrene-r-polybutadiene (PS-r-PB), polystyrene-r-polyisoprene (PS-r-PI), polystyrene-r-poly(methyl methacrylate) (PS-r-PMMA), polystyrene-r-poly(2-vinylpyridine) (PS-r-P2VP), polystyrene-r-poly(ferrocenyl-dimethylsilane) (PS-r-PFDMS), polystyrene-r-poly(tert-butylacrylate) (PS-r-PtBA), polystyrene-r-poly(ferrocenylethylmethylsilane) (PS-r-PFDMS), polyisoprene-r-poly(ethyleneoxide) (PI-r-PEO), polybutadiene-r-poly(butadiene-r-vinylpyridinium) (PB-r-PVP), poly(tert-butylacrylate)-r-poly(cinnamoyl-ethylmethacrylate) (PtBA-r-PCEMA), polystyrene-r-polyactide (PS-r-PLA), poly(α-methylstyrene)-r-poly(4-hydroxystyrene) (PαMS-r-PHS), pentadecyl phenol modified polystyrene-r-poly(4-vinylpyridine) (PPDPS-r-P4VP), poly(styrene-r-ethyleneoxide) (PS-r-PEO), polystyrene-r-poly(dimethyl siloxane) (PS-r-PDMS), polystyrene-r-polyethylene (PS-r-PE), polystyrene-r-poly(ferrocenyl dimethyl silane) (PS-r-PFS), polystyrene-r-poly(paraphenylene) (PS-r-PPP), PS-r-PB-r-PS, PS-r-PI-r-PS, poly(propyleneoxide))-r-PEO PPO-r-PEO, poly(4-vinyl-phenyldimethyl-2-propoxysilane) (PVPDMPS)-r-PI-r-PVPDMPS, PS-r-P2VP-r-PtBMA, or a copolymer thereof.

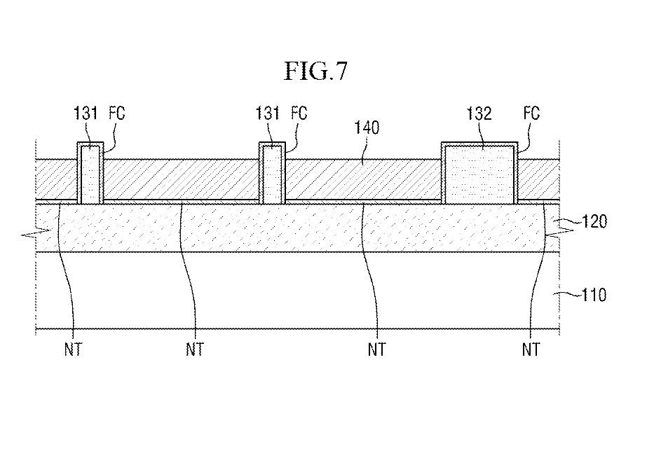

Referring to FIG. 7, a block copolymer 140 including a first repeating unit and a second repeating unit may fill each of the trenches T between the surface-reformed linear structures SM.

In one embodiment, the block copolymer 140 may be polystyrene-b-polybutadiene (PS-b-PB), polystyrene-b-polyisoprene (PS-b-PI), polystyrene-b-poly(methyl methacrylate) (PS-b-PMMA), polystyrene-b-poly(2-vinylpyridine) (PS-b-P2VP), polystyrene-b-poly(ferrocenyl-dimethylsilane) (PS-b-PFDMS), polystyrene-b-poly(tert-butylacrylate) (PS-b-PtBA), polystyrene-b-poly(ferrocenylethylmethylsilane) (PS-b-PFEMS), polyisoprene-b-poly(ethyleneoxide) (PI-b-PEO), polybutadiene-b-poly(butadiene-b-vinylpyridinium) (PB-b-PVP), poly(tert-butylacrylate)-b-poly(cinnamoyl-ethylmethacrylate) (PtBA-b-PCEMA), polystyrene-b-polyactide (PS-b-PLA), poly(α-methylstyrene)-b-poly(4-hydroxystyrene) (PαMS-PHS), pentadecyl phenol modified polystyrene-b-poly(4-vinylpyridine) (PPDPS-b-P4VP), poly(styrene-b-ethyleneoxide) (PS-b-PEO), polystyrene-b-poly(dimethyl siloxane) (PS-b-PDMS), polystyrene-b-polyethylene) (PS-b-PE), polystyrene-b-poly(ferrocenyl dimethyl silane) (PS-b-PFS), polystyrene-b-poly(paraphenylene) (PS-b-PPP), PS-b-PB-b-PS, PS-b-PI-b-PS, poly(propyleneoxide)-b-PEOPPO-b-PEO, poly(4-vinyl-phenyldimethyl-2-propoxysilane) (PVPDMPS)-b-PI-b-PVPDMPS, PS-b-P2VP-b-PtBMA, or a block copolymer thereof.

The first repeating unit and the second repeating unit may have different chemical properties. The first repeating unit and the second repeating unit may be microphase-separated by self-assembly. The first repeating unit and the second repeating unit may have different etch rates, such that the first repeating unit and the second repeating unit may be selectively removed. One of the first repeating unit and the second repeating unit may have selective reactivity with the fluorocarbon surface modification layer FC.

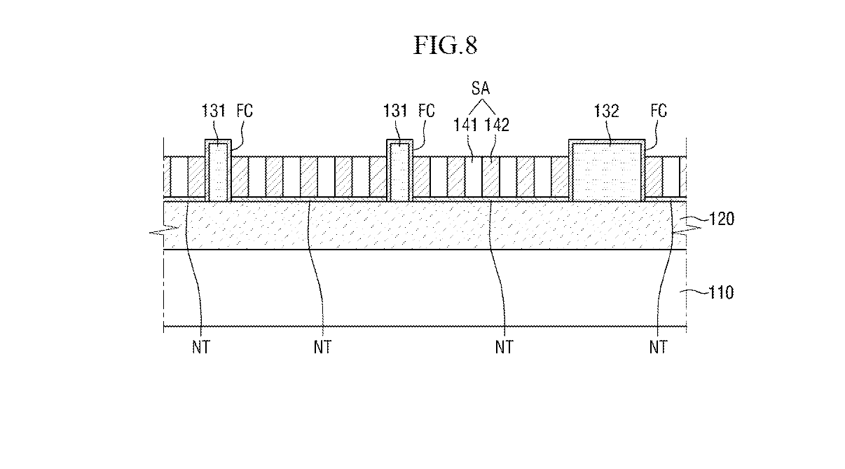

Referring to FIG. 8, self-assembled block copolymers SA may be formed. The self-assembly of the block copolymer 140 may be achieved by annealing. The annealing may include thermal annealing or solvent annealing.

Thermal annealing is a method of inducing microphase separation by heating a block copolymer to a glass transition temperature (Tg) (or higher) of the block copolymer. Solvent annealing is a method of inducing microphase separation by giving fluidity to a polymer chain by exposing a polymer thin layer containing a block copolymer to a solvent stream.

For example, to perform a solvent annealing process, a height of each of the first and second linear structures 131 and 132 after the trimming process may be 2.5 times greater than a height to which the block copolymer layer 140 is coated. In the solvent annealing process, swelling occurs when an evaporated solvent penetrates into a block copolymer. However, when the first and second linear structures 131 and 132 have the above-described heights, the block copolymer is prevented from flowing out of the trenches T beyond the surface-reformed linear structures SM.

Each of the self-assembled block copolymers SA includes a first domain 141 and a second domain 142. The first domain 141 includes a plurality of first repeating units, and the second domain 142 includes a plurality of second repeating units. The first domain 141 is formed by self-assembly of the first repeating units, and the second domain 142 is formed by self-assembly of the second repeating units.

The first domain 141 and the second domain 142 may be arranged alternately to form a lamellar structure. The second domain 142 is disposed adjacent to the fluorocarbon surface modification layer FC, and the first domain 141 is disposed between the second domains 142.

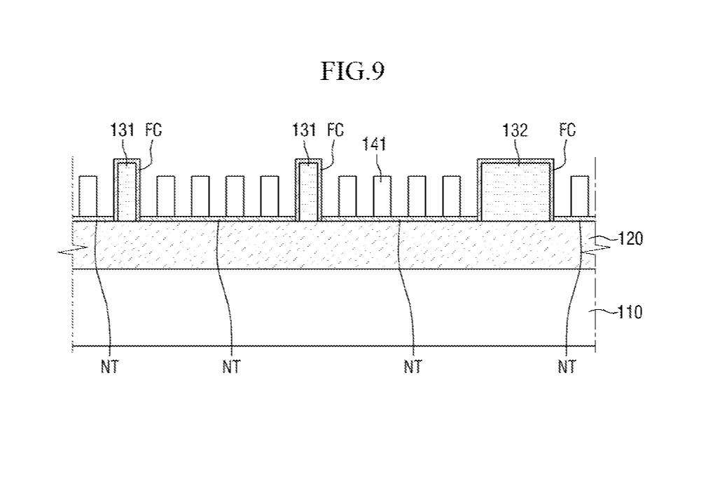

Referring to FIG. 9, only the second domains 142 may be removed. In removing only the second domains 142 from among the first domains 141 and the second domains 142, a solvent that has high affinity to the second domains 142 may be used. However, the inventive concept is not limited thereto. In some embodiments, the second domains 142 can also be removed by a thy-etching process. The thy-etching process may include using a gas such as oxygen, a carbon fluoride gas, or hydrogen fluoride (HT).

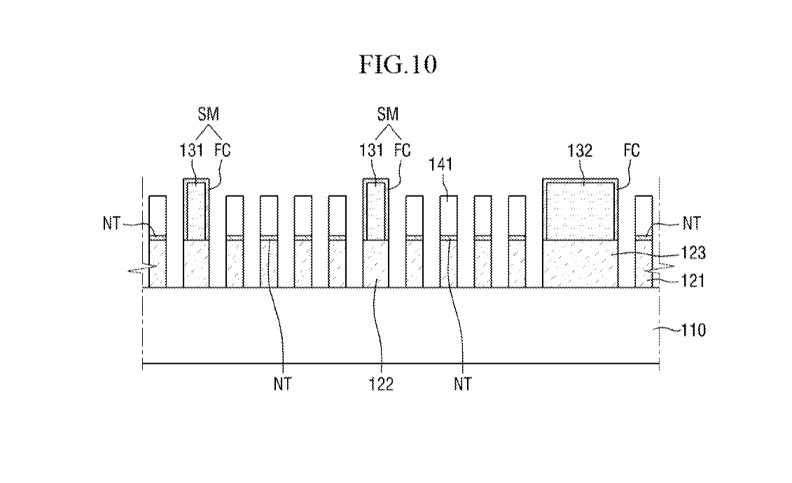

Referring to FIG. 10, the electrical conductive layer 120 may be etched using the first domains 141 and the surface-reformed linear structures SM as a mask. Accordingly, first and second conductive wire patterns 121 and 122 and a reflective layer 123 may be formed on the substrate 110.

The resulting structure in FIG. 10 constitutes a wire grid polarizer. The wire grid polarizer includes the substrate 110, the first and second conductive wire patterns 121 and 122 disposed on the substrate 110, the first domains 141 respectively disposed on the first conductive wire patterns 121, and the surface-reformed linear structures SM respectively disposed on the second conductive wire patterns 122 and the reflective layer 123.

If the etching process is performed such that the surface-reformed linear structures SM and the first domains 141 are not completely removed, the first domains 141 may remain on the first conductive wire patterns 121, and the surface-reformed linear structures SM may remain on the second conductive wire patterns 122 and the reflective layer 123.

The reflective layer 123 is wider than the first and second conductive wire patterns 121 and 122. In the example of FIG. 10, the reflective layer 123 is disposed parallel to the first and second conductive wire patterns 122 and 123. However, in some embodiments (not shown), the reflective layer 123 may further include an extension portion disposed perpendicular to the first and second conductive wire patterns 122 and 123. Within a display device, the reflective layer 123 may be disposed in a light-blocking layer, for example, in a region overlapping a black matrix. The reflective layer 123 may reflect light reflected by the first and second conductive wire patterns 121 and 122 or light directly incident thereupon, such that the reflected light can be transmitted by the first and second conductive wire patterns 121 and 122. Accordingly, the reflective layer 123 can be used to improve the luminance of the display device.

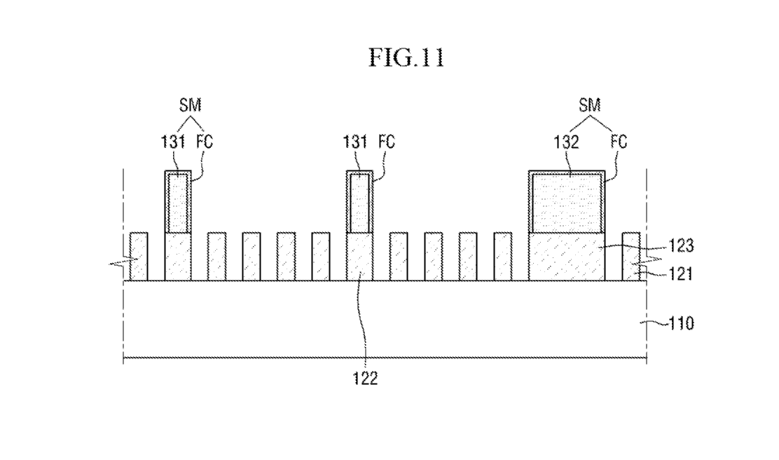

FIG. 11 illustrates a cross-sectional view of a wire grid polarizer according to another embodiment. Referring to FIG. 11, the wire grid polarizer includes a substrate 110, first and second conductive wire patterns 121 and 122 disposed on the substrate 110, and surface-reformed linear structures SM respectively disposed on the second conductive wire patterns 122 and a reflective layer 123.

Comparing FIGS. 10 and 11, first domains 141 are not located on the first conductive wire patterns 121 in the example of FIG. 11, but are located on the first conductive wire patterns 121 in the example of FIG. 10. In addition, a neutral layer NT is not located on each of the first conductive wire patterns 121 in the example of FIG. 11, but is located on each of the first conductive wire patterns 121 in the example of FIG. 10.

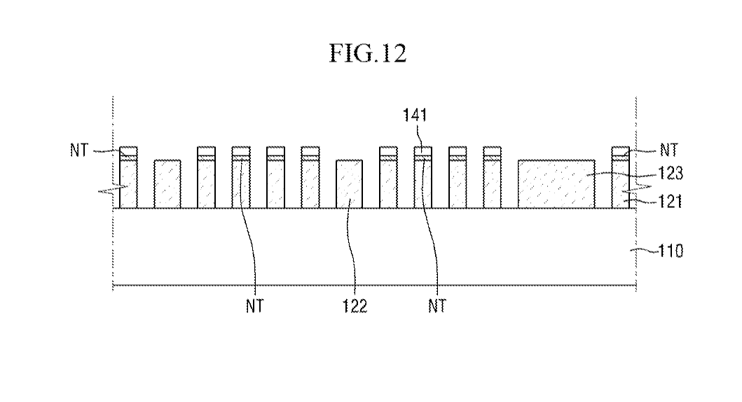

FIG. 12 illustrates a cross-sectional view of a wire grid polarizer according to another embodiment. Referring to FIG. 12, the wire grid polarizer includes a substrate 110, first and second conductive wire patterns 121 and 122 disposed on the substrate 110, and first domains 141 located on the first conductive wire patterns 121.

Comparing FIGS. 10 and 12, surface-reformed linear structures SM are not located on the second conductive wire patterns 122 in the example of FIG. 12, but are located on the second conductive wire patterns 122 in the example of FIG. 10. In addition, a surface-reformed linear structure SM is not located on a reflective layer 123 in the example of FIG. 12, but is located on the reflective layer 123 in the example of FIG. 10.

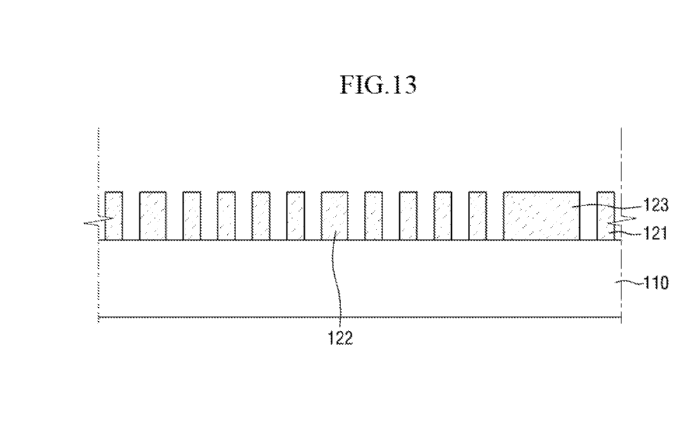

FIG. 13 illustrates a cross-sectional view of a wire grid polarizer according to another embodiment. Referring to FIG. 13, the wire grid polarizer includes a substrate 110 and conductive wire patterns 121 and 122 and a reflective layer 123 disposed on the substrate 110.

In the example of FIG. 13, surface-reformed linear structures SM and first domains 141 remaining on the conductive wire patterns 121 and 122 and the reflective layer 123 may be entirely removed. As a result, only the conductive wire patterns 121 and 122 and the reflective layer 123 remain on the substrate 110.

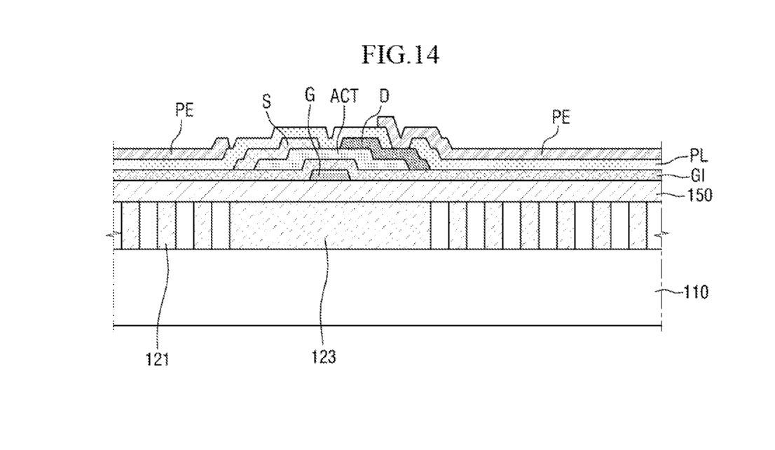

FIG. 14 illustrates a schematic cross-sectional view of a lower substrate of a display device according to an embodiment.

Referring to FIG. 14, the lower substrate may be a thin-film transistor (TFT) substrate. A TFT may be configured as follows. A gate electrode G is located on a protective layer 150, and a gate insulating layer GI is located on the gate electrode G and the protective layer 150. A semiconductor layer ACT is located on at least a region of the gate insulating layer GI which overlaps the gate electrode G, and a source electrode S and a drain electrode D are located on the semiconductor layer ACT and separated from each other. A passivation layer PL is located on the gate insulating layer GI, the source electrode S, the semiconductor layer ACT, and the drain electrode D. A pixel electrode PE is located on the passivation layer PL and electrically connected to the drain electrode D via a contact hole partially exposing the drain electrode D.

A region in which the TFT is located does not transmit light. Thus, the region in which the ITT is located corresponds to a non-aperture region. A reflective layer 123 may be disposed under the TFT. When the reflective layer 123 is made of a metal material having high reflectivity, it may reflect light incident upon the non-aperture region, and the reflected light may be transmitted in an aperture region. Accordingly, the luminance of the display device can be improved.

Although not illustrated in FIG. 14, the display device may further include a backlight unit capable of emitting light, an upper substrate facing the lower substrate, a liquid crystal layer disposed between the lower substrate and the upper substrate, and an upper polarizing plate located on the upper substrate.

In some embodiments, transmission axes of the upper polarizing plate and a wire grid polarizer may be orthogonal or parallel to each other. The upper polarizing plate can be formed as a wire grid polarizer, or may be a conventional polyvinyl acetate (PVA)-based polarizing film. In some alternative embodiments, the upper polarizing plate may be omitted.

The backlight unit may include a light guide plate (LGP), one or more light source units, a reflective member, an optical sheet, etc.

The LGP is configured to change the path of light generated by the light source units toward the liquid crystal layer. The LGP may include an incident surface upon which light generated by the light source units is incident, and an exit surface facing the liquid crystal layer. The LGP may be made of a material having light-transmitting properties such as polymethyl methacrylate (PMMA), or a material having a constant refractive index such as polycarbonate (PC).

Light incident upon a side surface or on both side surfaces of the LGP made of the above materials has an angle smaller than a critical angle of the LGP. Thus, the light is delivered into the LGP. When the light is incident upon an upper or lower surface of the LGP, an incidence angle of the light is greater than the critical angle. Thus, the light is evenly delivered within the LGP without exiting from the LGP.

Scattering patterns may be formed on any one of the upper and lower surfaces of the LGP. For example, the scattering patterns may be formed on the lower surface of the LGP which faces the exit surface, such that the guided light travels upward. That is, the scattering patterns may be printed on a surface of the LGP, such that light reaching the scattering patterns within the LGP can exit upward from the LGP. The scattering patterns can be printed using ink. However, the inventive concept is not limited thereto. In some embodiments, the scattering patterns can be provided in various forms such as micro grooves or micro protrusions formed on the LGP.

The reflective member may be further provided between the LGP and a bottom portion of a lower housing member. The reflective member reflects light that is output from the lower surface (facing the exit surface) of the LGP back to the LGP. In some embodiments, the reflective member may be provided as a film.

The light source units may be placed facing the incident surface of the LGP. The number of light source units can be changed as desired. For example, in some embodiments, only one light source unit may be disposed corresponding to a side surface of the LGP. In other embodiments, three or more light source units may be disposed corresponding to three out of four side surfaces (or all four side surfaces) of the LGP. In some alternative embodiments, a plurality of light source units may be disposed corresponding to any one of the side surfaces of the LGP. While a side light structure in which a light source is placed on one side of the LGP has been described as an example, it should be noted that a direct structure, a surface light source structure, or any other appropriate structures can also be used depending on the configuration of the backlight unit.

A light source may be a white light-emitting diode (LED) capable of emitting white light. In some embodiments, the light source may include a plurality of LEDs capable of emitting red light, green light, and blue light. When the light source includes a plurality of LEDs capable of emitting red light, green light, and blue light, the LEDs may be turned on simultaneously to produce white light through color mixing.

The upper substrate may be a color filter (CF) substrate. The upper substrate may include a black matrix for preventing light leakage, and a common electrode (e.g., an electric field-generating electrode) made of a transparent conductive oxide such as indium tin oxide (ITO) or indium zinc oxide (IZO). The black matrix and the common electrode may be formed on a lower surface of a member made of a transparent insulating material such as glass or plastic.

The liquid crystal layer can rotate a polarization axis of incident light. The liquid crystal layer is aligned in a specific direction and located between the upper substrate and the lower substrate. The liquid crystal layer may be provided in different modes, for example, a twisted nematic (TN) mode, a vertical alignment (VA) mode, or a horizontal alignment (IPS, FFS) mode having positive dielectric anisotropy.

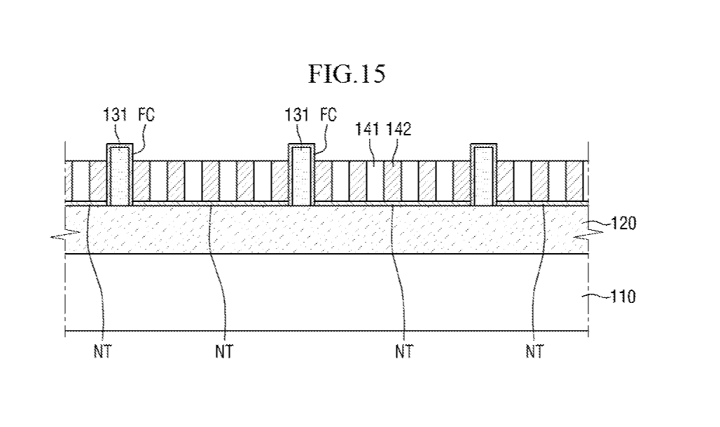

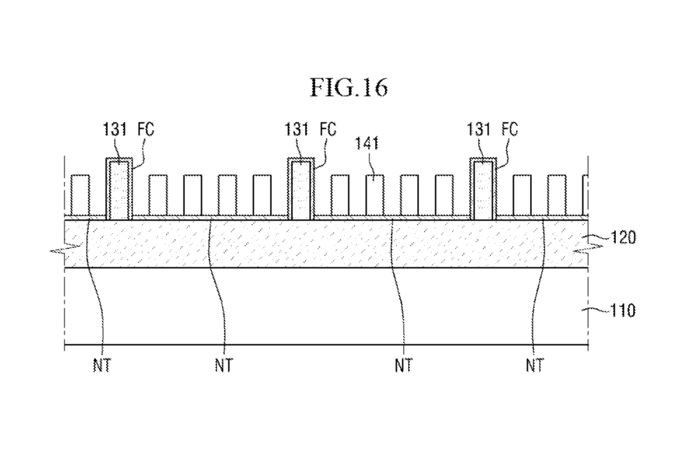

FIGS. 15 and 16 illustrate cross-sectional views of another exemplary wire grid polarizer at different stages of fabrication according to a method of manufacturing the wire grid polarizer.

As previously noted, the second linear structure 132 is formed in the method described in FIGS. 1 through 9. In contrast, a second linear structure is not formed on an electrical conductive layer 120 in the method described in FIGS. 15 and 16. In particular, a reflective layer is not formed in the embodiment of FIG. 16.

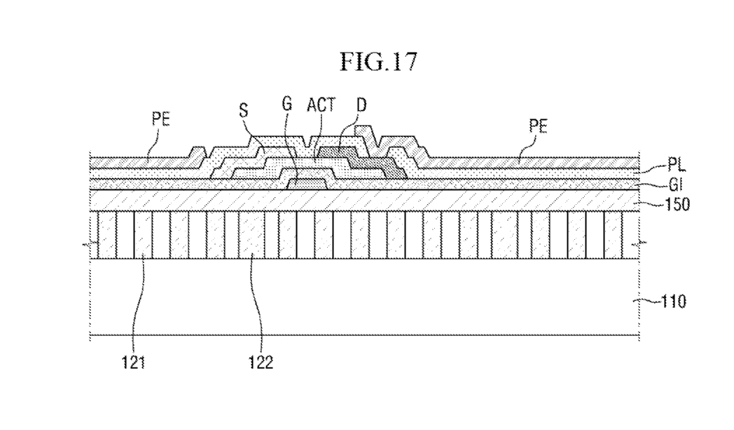

FIG. 17 illustrates a schematic cross-sectional view of a lower substrate of a display device according to another embodiment. Specifically, the lower substrate of FIG. 17 may be manufactured using the method described in FIGS. 15 and 16.

The lower substrate of FIG. 17 differs from the lower substrate of FIG. 14 as follows. Specifically, in the lower substrate of FIG. 17, only the first conductive wire patterns 121 and the second conductive wire patterns 122 are disposed on a substrate 110, and a reflective layer is not located under a TFT.

While the inventive concept have been illustrated and described with reference to exemplary embodiments, it will be understood by one of ordinary skill in the art that various changes may be made to the embodiments without departing from the spirit and scope of the inventive concept. Furthermore, the embodiments should be construed in a descriptive sense and should not construed in a limiting manner.

What is claimed is:

1. A method of manufacturing a wire grid polarizer, comprising:
forming an electrical conductive layer on a substrate;
forming a guide pattern layer on the electrical conductive layer, wherein the guide pattern layer comprises two or more linear structures separated from one another;
forming a fluorocarbon surface modification layer on each of the linear structures using a fluorine-based gas plasma treatment; and
forming a neutral layer on the electrical conductive layer, wherein the neutral layer has a nonselective affinity with repeating units of a block copolymer.

2. The method of claim 1, wherein the fluorine-based gas comprises at least one of sulfur hexafluoride (SF₆) and nitrogen hexafluoride (NF₆), or a carbon fluoride-based gas.

3. The method of claim 1, wherein the fluorine-based gas is a gas mixture comprising a carbon fluoride-based gas and at least one of sulfur hexafluoride (SF₆) and nitrogen hexafluoride (NF₆), wherein a content of the carbon fluoride-based gas is equal to or less than 30% of a total content of the fluorine-based gas.

4. The method of claim 1, wherein the neutral layer is made of a random copolymer comprising a first repeating unit and a second repeating unit, wherein the random copolymer comprises at least one of polystyrene-r-polybutadiene (PS-r-PB), polystyrene-r-polyisoprene (PS-r-PI), polystyrene-r-poly(methyl methacrylate) (PS-r-PMMA), polystyrene-r-poly(2-vinylpyridine) (PS-r-P2VP), polystyrene-r-poly(ferrocenyl-dimethylsilane) (PS-r-PFDMS), polystyrene-r-poly(tert-butylacrylate) (PS-r-PtBA), polystyrene-r-poly(ferrocenylethylmethylsilane) (PS-r-PFEMS), polyisoprene-r-poly(ethyleneoxide) (PI-r-PEO), polybutadiene-r-poly(butadiene-r-vinylpyridinium) (PB-r-PVP), poly(tert-butylacrylate)-r-poly(cinnamoyl-ethylmethacrylate) (PtBA-r-PCEMA), polystyrene-r-polyactide (PS-r-PLA), poly(α-methylstyrene)-r-poly(4-hydroxystyrene) (PαMS-r-PHS), pentadecyl phenol modified polystyrene-r-poly(4-vinylpyridine) (PPDPS-r-P4VP), poly(styrene-r-ethyleneoxide) (PS-r-PEO), polystyrene-r-poly(dimethyl siloxane) (PS-r-PDMS), polystyrene-r-polyethylene (PS-r-PE), polystyrene-r-poly(ferrocenyl dimethyl silane) (PS-r-PFS), polystyrene-r-poly(paraphenylene) (PS-r-PPP), PS-r-PB-r-PS, PS-r-PI-r-PS, poly(propyleneoxide))-r-PEO (PPO-r-PEO), and poly(4-vinyl-phenyldimethyl-2-propoxysilane) (PVPDMPS)-r-PI-r-PVPDMPS, PS-r-P2VP-r-PtBMA), or a copolymer thereof.

5. The method of claim 1, wherein forming the guide pattern layer comprises:
forming an organic matter layer on the electrical conductive layer;
forming the two or more linear structures by etching the organic matter layer; and
reducing a width of each of the linear structures.

6. The method of claim 5, wherein the width of each of the linear structures is reduced using a plasma etching process.

7. The method of claim 6, wherein the plasma etching process is an oxygen plasma etching process.

8. The method of claim 1, further comprising:
forming a self-assembled block copolymer layer in a trench between surface-reformed linear structures, wherein the self-assembled block copolymer layer comprises a first domain formed by self-assembly of the first repeating unit and a second domain formed by self-assembly of the second repeating unit; and
removing one of the first domain and the second domain.

9. The method of claim 8, wherein forming the self-assembled block copolymer layer comprises:
forming a block copolymer layer in a trench between the linear structures, wherein the block copolymer layer comprises the first repeating unit and the second repeating unit; and
annealing the block copolymer layer.

10. The method of claim 9, wherein the block copolymer layer comprises at least one of polystyrene-b-polybutadiene (PS-b-PB), polystyrene-b-polyisoprene (PS-b-PI), polystyrene-b-poly(methyl methacrylate) (PS-b-PMMA), polystyrene-b-poly(2-vinylpyridine) (PS-b-P2VP), polystyrene-b-poly(ferrocenyl-dimethylsilane) (PS-b-PFDMS), polystyrene-b-poly(tert-butylacrylate) (PS-b-PtBA), polystyrene-b-poly(ferrocenylethylmethylsilane) (PS-b-PFEMS), polyisoprene-b-poly(ethyleneoxide) (PI-b-PEO), polybutadiene-b-poly(butadiene-b-vinylpyridinium) (PB-b-PVP), poly(tert-butylacrylate)-b-poly(cinnamoyl-ethylmethacrylate) (PtBA-b-PCEMA), polystyrene-b-polyactide (PS-b-PLA), poly(α-methylstyrene)-b-poly(4-hydroxystyrene) (PαMS-b-PHS), pentadecyl phenol modified polystyrene-b-poly(4-vinylpyridine) (PPDPS-b-P4VP), poly(styrene-b-ethyleneoxide) (PS-b-PEO), polystyrene-b-poly(dimethyl siloxane) (PS-b-PDMS), polystyrene-b-polyethylene) (PS-b-PE), polystyrene-b-poly(ferrocenyl dimethyl silane) (PS-b-PFS), polystyrene-b-poly(paraphenylene) (PS-b-PPP), PS-b-PB-b-PS, poly(propyleneoxide)-b-PEO PPO-b-PEO, and poly(4-vinyl-phenyldimethyl-2-propoxysilane) (PVPDMPS)-b-PI-b-PVPDMPS, PS-b-P2VP-b-PtBMA), or a block copolymer thereof.

11. The method of claim 9, wherein the annealing of the block copolymer layer includes thermal annealing or solvent annealing.

12. The method of claim 8, further comprising: patterning the electrical conductive layer using a remaining domain and the surface-modified linear structures.

13. The method of claim 1, wherein the substrate comprises at least one of glass, quartz, and a polymer compound.

14. The method of claim 1, wherein the electrical conductive layer is a metal layer.

15. The method of claim 14, wherein the metal layer comprises at least one of aluminum (Al), chrome (Cr), silver (Ag), copper (Cu), nickel (Ni), titanium (Ti), cobalt (Co), and molybdenum (Mo), or any alloy thereof.

16. A wire grid polarizer comprising:
a substrate;
a plurality of conductive wire patterns disposed on the substrate;
an organic matter layer disposed on the conductive wire patterns; and
a fluorocarbon surface modification layer disposed on the organic matter layer.

17. The wire grid polarizer of claim 16, wherein the plurality of conductive wire patterns comprise a first conductive wire pattern having a first width and a second conductive wire pattern having a second width, and wherein the second width is greater than the first width.

18. The wire grid polarizer of claim 16, wherein the organic matter layer and the fluorocarbon surface modification layer are disposed on the second conductive wire pattern.

19. The wire grid polarizer of claim 17, further comprising a remaining domain layer disposed on the first conductive wire pattern.

20. The wire grid polarizer of claim 16, farther comprising a reflective layer, wherein the organic matter layer and the fluorocarbon surface modification layer are disposed on the reflective layer.
